(19) United States
(12) Patent Application Publication
(10) Pub. No.: US 2007/0048983 A1
(43) Pub. Date: Mar. 1, 2007

(54) Method of fabricating silicon thin film layer

(76) Inventors: Do-Young Kim, Suwon-si (KR); Jong-man Kim, Suwon-si (KR); Ji-sim Jung, Incheon-si (KR); Takashi Noguchi, Yongin-si (KR); Jang-yeon Kwon, Seongnam-si (KR)

Correspondence Address: CANTOR COLBURN, LLP, 55 GRIFFIN ROAD SOUTH, BLOOMFIELD, CT, 06002, US

(21) Appl. No.: 11/498,693

(22) Filed: Aug. 3, 2006

(30) Foreign Application Priority Data
Aug. 26, 2005 (KR) 10-2005-0078881

(51) Int. Cl. H01L 21/265

(52) U.S. Cl. 438/520; 257/E21.319

(57) ABSTRACT

A method of fabricating a high-quality silicon thin layer includes making Xe ions generated by RF power collide with a silicon target material layer to generate silicon particles from the silicon target material layer; and depositing the silicon particles on a predetermined substrate. The method is performed under a pressure of about 5 mTorr or lower and at an RF power of about 200 W or more. In this method, the silicon thin layer is thermally stabilized, and the amount of gas captured in silicon crystals during the sputtering process is greatly reduced.

This application claims priority to Korean Patent Application No. 10-2005-0078881, filed on Aug. 26, 2005, and all the benefits accruing therefrom under 35 U.S.C. §119, and the contents, the of which in its entirety are herein incorporated by reference.

### BACKGROUND OF THE INVENTION

1. Field of the Invention The present invention relates to a method of fabricating a silicon thin film layer, and more particularly, to a method of fabricating a high-quality silicon thin film layer by reducing the amount of captured process gas used for formation of the silicon thin film layer.

2. Description of the Related Art

Polycrystalline silicon.(“poly-Si”) has higher mobility and better optical stability than amorphous silicon (“a—Si”). The poly-Si is applied in various fields, particularly, thin film transistors (“TFTs”) and memory devices. For example, a poly-Si TFT is used as a switching device for a display device. An active device like a TFT is utilized for display devices, such as a thin film transistor liquid crystal display (“TFT-LCD”) and a thin film transistor organic light emitting display (“TFT-OLED”).

The display device, such as the TFT-LCD and the TFT-OLED, is structured such that a plurality of pixels are arranged in an X-Y matrix, and each pixel includes a TFT. Therefore, the performance of the LCD or OLED with a plurality of TFTs is greatly affected by the electrical properties of the TFTs. Here, the mobility of a Si active layer is considered as one of the most important properties of the TFTs. Crystallization of Si increases the mobility of the Si active layer. In this respect, research on crystallization of Si centers on development of poly-Si approximating single crystalline Si. U.S. Pat. No. 6,322,625 discloses a method of fabricating a high-quality crystalline Si. With the advance of crystallization of Si, a poly-Si structure resembling single crystalline Si is being fabricated.

Meanwhile, there have been studies on an LCD using a substrate (e.g., a plastic substrate), which is vulnerable to heat but elastic and flexible, instead of a hard and heat-resistant substrate (e.g., a glass substrate). The use of the plastic substrate instead of the glass substrate can further strengthen the price competitiveness of LCDs. Also, the plastic substrate is indispensable for a paper-like display that is under study as an advanced model for an LCD.

However, since the plastic substrate is quite vulnerable to heat, application of the plastic substrate to LCDs necessitates a low-temperature process. U.S. Pat. No. 5,817,550 to Carry et al. introduces a method of preventing damage of a plastic substrate during formation of a Si channel on the plastic substrate.

Typically, an amorphous silicon (a—Si) layer is deposited using a chemical vapor deposition (“CVD”) process. However, considering that 10% to 20% of the hydrogen process gas exists in the formed crystals, a sputtering process using Ar gas is appropriate to obtain a high-quality poly-Si layer. The sputtering process using the Ar process gas allows the capturing rate of Ar gas to be as low as 1% to 3%. The lower the capturing rate of a process gas becomes, the better the quality of the poly-Si layer becomes. Accordingly, there is a desire to develop a new method for dropping the capturing rate of the process gas used for formation of the Si layer.

### BRIEF SUMMARY OF THE INVENTION

The present invention provides a method of fabricating a Si thin film layer that can effectively reduce the capturing rate of a process gas used for formation of the Si thin film layer.

According to an exemplary embodiment of the present invention, a method of fabricating a Si thin film layer includes forming a silicon (Si) thin film layer on a substrate through a radio-frequency (“RF”) sputtering process using xenon (Xe) gas. In this case, the RF sputtering process is performed under a pressure of about 5 mTorr or lower and at an RF power of about 200 W or more.

The method according to exemplary embodiments of the present invention may further include annealing the Si thin layer at a predetermined temperature.

Also, the Si thin layer may be annealed using an eximer laser.

In the present invention, the sputtering process is carried out using Xe gas, which is an inert gas with a much greater mass than Si. Owing to a difference in mass between Xe and Si, repulsion of Xe occurs at a low speed during collision of Si particles torn out from a Si target layer with neutral Xe. Thus, the amount of Xe that moves toward the substrate on which the Si particles are deposited is reduced. As a result, the amount of captured Xe in the Si thin layer decreases.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram illustrating an exemplary embodiment of a method of forming a Si thin layer according to the present invention;

FIG. 2 is a cross-sectional view of an exemplary sample for making a Si thin layer formed on a Si wafer according to the present invention;

FIGS. 3A and 3B are graphs showing Rutherford backscattering spectroscopy (“RBS”) data of a Si thin layer obtained using a conventional Ar sputtering process;

FIGS. 4A and 4B are graphs showing RBS data of an exemplary Si thin layer obtained using an Xe sputtering process according to the present invention;

FIG. 5 is a graph showing x-ray photoelectron spectrometry (“XPS”) data of the Si thin layer obtained using the conventional Ar sputtering process;

FIG. 6 is a graph showing XPS data of the Si thin layer obtained using the Xe sputtering process according to the present invention;

FIGS. 7A and 7B are tables showing the thermal durability of the Si thin layer obtained using the conventional Ar sputtering process and the exemplary Si thin layer obtained using the Xe sputtering process according to the present invention;

FIGS. 8A and 8B are scanning electron microscope (“SEM”) images showing crystalline structures of the Si thin layer obtained using the conventional Ar sputtering process before and after an eximer laser annealing (“ELA”) process, respectively;

FIGS. 9A and 9B are electron microscopes showing crystalline structures of the exemplary Si thin layer obtained using the Xe sputtering process according to the present invention before and after an ELA process, respectively;

FIGS. 10A and 10B are SEM images of samples of a Si thin layer obtained using an Xe sputtering process under different conditions, on which an annealing process is performed;

FIG. 11 is a graph showing variations of O₂ contents of the samples shown in FIGS. 10A and 10B;

FIG. 12 is a graph of ultraviolet (“UV”) reflectance with respect to laser energy density in the samples shown in FIGS. 10A and 10B;

FIG. 13 is an SEM image of samples of a Si layer that are obtained using an Xe sputtering process under different conditions and annealed at an energy density of 550 mJ/cm²;

FIGS. 14A and 14B are graphs showing the measurements of O₂ and Xe contents of the samples shown in FIG. 13; and

FIG. 15 is a graph of 200 nm-UV reflectance and laser energy density with respect to O₂ content in exemplary samples that are obtained according to the present invention.

### DETAILED DESCRIPTION OF THE INVENTION

Hereinafter, the present invention will be described more fully with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, lengths and sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “below” or “lower” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

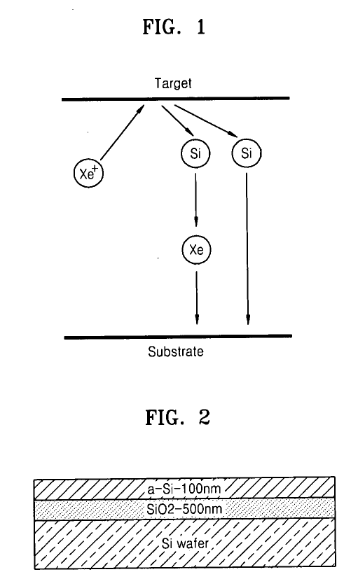

FIG. 1 is a schematic diagram illustrating a process of capturing a sputtering gas while depositing a Si layer using a sputtering process.

Referring to FIG. 1, when Xe is ionized due to radio-frequency (“RF”) power, Xe⁺ collides with a Si target layer. As a result, Si particles are torn out from the Si target layer and accumulate on a substrate. In this case, it is probable that some of the Si particles collide with neutral Xe. Thus, Xe is shocked by the Si particles and becomes repulsive. However, since Xe has a much greater mass than Si, the repulsion of the Xe weakly occurs. Accordingly, only a small amount of Xe is captured in the Si thin layer even with the repulsion of Xe due to the Si particles. However, if Ar is used as a sputtering gas instead of Xe, since Ar has a smaller mass than Xe, the capturing rate of Ar would be higher than that of Xe. That is, the capturing rate of Ar reaches about 1% to about 3%. It is experimentally confirmed that the capturing rate of Xe is relatively low, as herein described below.

In order to look into the effect of the present invention, samples were prepared as shown in FIG. 2. For brevity of explanation, a Si wafer was used instead of a plastic substrate, and a SiO₂ thin layer was formed on the Si wafer to a thickness of 500 nm. Thereafter, an amorphous Si (a—Si) thin layer was formed on the SiO₂ thin layer to a thickness of 100 nm using an RF sputtering process performed at a room temperature. In order to obtain results for comparison, two samples were formed using conventionally used Ar gas and Xe gas according to the present invention, respectively. By using the two samples, the capturing rate of each of the Ar gas and Xe gas was measured using Rutherford backscattering spectroscopy (“RBS”) and x-ray photoelectron spectrometry (“XPS”).

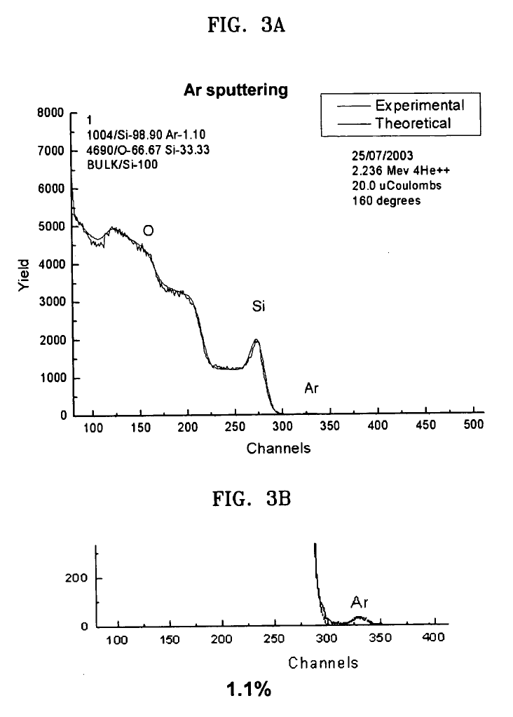

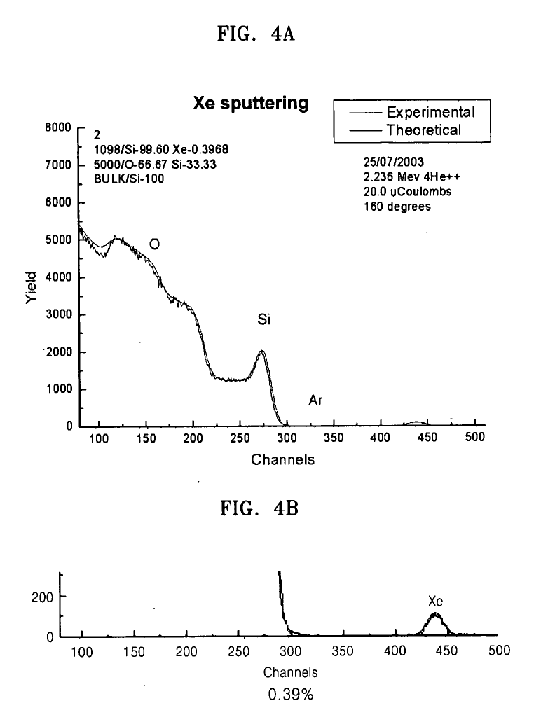

FIGS. 3A and 4A are graphs showing RBS data of Si thin layers obtained using a conventional Ar sputtering process and an exemplary Xe sputtering process according to the present invention, respectively. FIGS. 3B and 4B are graphs showing enlargements of an Ar region and an Xe region of FIGS. 3A and 4A, respectively.

In FIGS. 3A through 4B, experimental values are illustrated with saw-toothed lines, and theoretical values are illustrated with smooth lines.

Referring to FIGS. 3A and 3B, the Si thin layer formed using the conventional Ar sputtering process obtained Ar data between 300 and 350 channels, and the capturing rate of Ar was 1.1%.

Referring to FIGS. 4A and 4B, the Si thin layer formed using the exemplary Xe sputtering process according to the present invention obtained Xe data between 400 to 450 channels, and the capturing rate of Xe was 0.39%.

From FIGS. 3A through 4B, it can be demonstrated that the method of forming the Si thin layer using the exemplary Xe sputtering process according to the present invention greatly reduces the amount of gas captured in the Si thin layer.

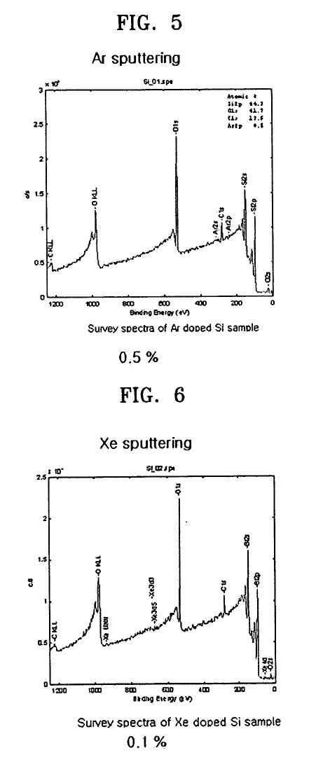

FIG. 5 is a graph showing XPS data of the Si thin layer obtained using the conventional Ar sputtering process. FIG. 6 is a graph showing XPS data of the Si thin layer obtained using the exemplary Xe sputtering process according to the present invention. Referring to FIG. 5, the Ar sputtering process leads to formation of the Si thin layer with an Ar content of 0.5%. Referring to FIG. 6, the exemplary Xe sputtering process leads to formation of the Si thin layer with an Xe content of 0.1%. Therefore, from comparison of the XPS data shown in FIGS. 5 and 6, it can be seen that the exemplary Xe sputtering process according to the present invention enables formation of a Si thin layer with a reduced gas content.

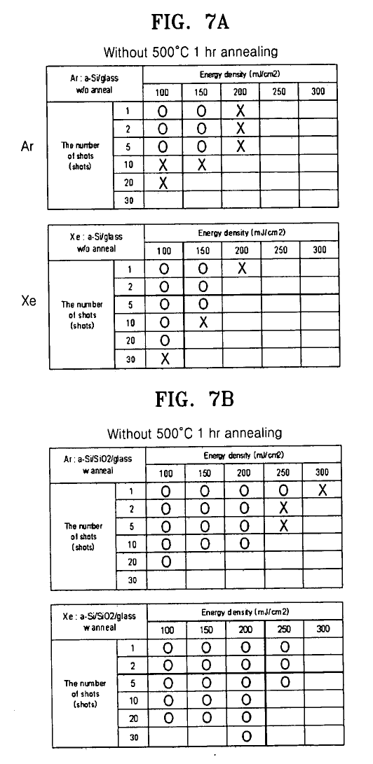

FIG. 7A shows tables of the thermal durability of the Si thin layer obtained using the conventional Ar sputtering process and the Si thin layer obtained using the exemplary Xe sputtering process according to the present invention before an annealing process. In FIG. 7A, the tables show whether there are any defects caused by gas injection in the Si thin layers depending on the number of shots of eximer laser irradiation and energy density. Thus, if there was any defect caused by gas injection, it was denoted by “X” in the tables, and if there was no defect caused by gas injection, it was denoted by “O” in the tables. Each sample (i.e., the Si thin layers) was obtained by forming a 200 nm SiO₂ thin layer on a glass substrate and forming a 50 nm a—Si layer thereon. In this experiment, the conventional Ar sputtering process and the exemplary Xe sputtering process were performed under a pressure of 5 mTorr, at an RF power of 200 W, and at room temperature.

Referring to FIG. 7A, in the Si thin layer obtained using the conventional Ar sputtering process, when an eximer laser was irradiated with only one shot at an energy density of 200 mJ/cm², defects were generated. Also, when the eximer laser was irradiated with 10 shots at an energy density was 100 to 150 mJ/cm², there were defects.

In the Si thin layer obtained using the exemplary Xe sputtering process, when the eximer laser was irradiated at an energy density of 100 mJ/cm², no defects were generated with 20 shots of eximer laser irradiations, while some defects were found with 30 shots. Also, when the eximer laser was irradiated with 10 shots at an energy density was 150 mJ/cm², there were defects.

From the results of FIG. 7A, it can be known that the Si thin layer obtained using the exemplary Xe sputtering process is more thermally stable than the Si thin layer obtained using the conventional Ar sputtering process.

FIG. 7B shows tables of the thermal durability of the Si thin layer obtained using the conventional Ar sputtering process and the Si thin layer obtained using the exemplary Xe sputtering process according to the present invention after an eximer laser annealing (“ELA”) process. In FIG. 7B, the tables show ELA results after the two samples were annealed at a temperature of about 500° C. and irradiated under the same process conditions as described with reference to FIG. 7A.

Referring to FIG. 7B, in the Si thin layer obtained using the Ar sputtering process, when the eximer laser was irradiated with only one shot at an energy density of 300 mJ/cm², defects were generated. However, in the Si thin layer obtained using the Xe sputtering process, even if the eximer laser was irradiated with five shots or more at an energy density of 250 mJ/cm², no defects were generated. When an energy density was about 200 mJ/cm² or lower, no defects were found even with 5 to 30 shots of eximer laser irradiation.

From the results of FIG. 7B, it can be confirmed once again that the Si thin layer obtained using the exemplary Xe sputtering process is more thermally stable than the Si thin layer obtained using the conventional Ar sputtering process.

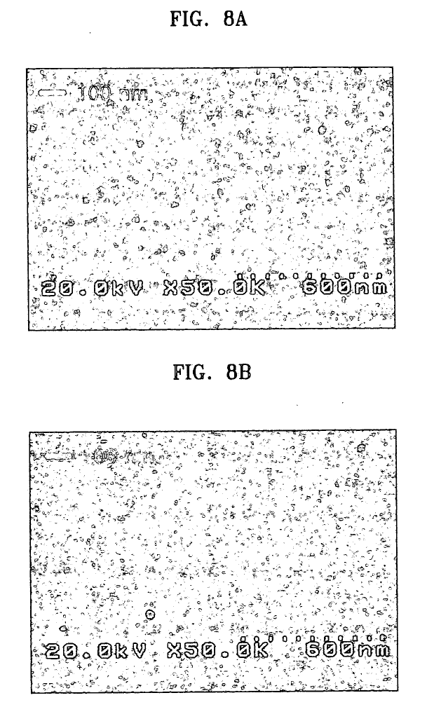

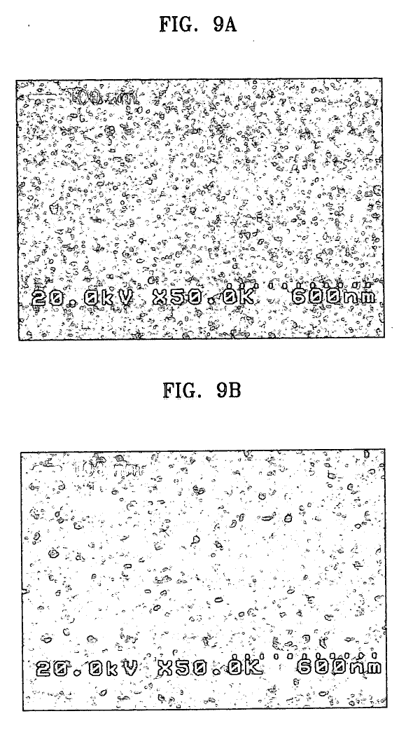

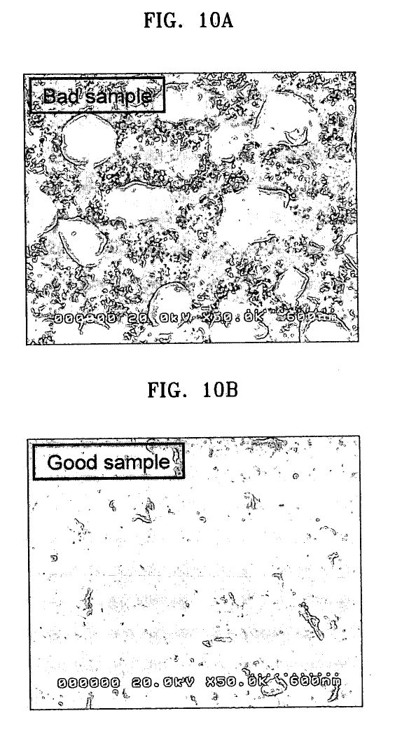

FIGS. 8A and 8B are scanning electron microscope (“SEM”) images showing crystalline structures of the Si thin layer obtained using the conventional Ar sputtering process before and after an ELA process, respectively. Also, FIGS. 9A and 9B are SEM images showing crystalline structures of the Si thin layer obtained using the exemplary Xe sputtering process according to the present invention before and after an ELA process, respectively.

On comparing FIGS. 8A and 9A, which shows the crystalline structures of the Si thin layers obtained using the conventional Ar sputtering process and the exemplary Xe sputtering process, respectively, it can be observed that crystals of the Si thin layer obtained using the exemplary Xe sputtering process have clearer and more uniform boundaries than crystals of the Si thin layer obtained using the conventional Ar sputtering process.

FIGS. 8B and 9B shows crystal grains of the Si thin layers obtained using the conventional Ar sputtering process and the exemplary Xe sputtering process, respectively, on which an ELA process was performed at a temperature of 500° C. In comparison to the Si thin layer formed using the Ar sputtering process as shown in FIG. 8B, the Si thin layer formed using the exemplary Xe sputtering process as shown in FIG. 9B has greater crystal grains after the ELA process.

Meanwhile, the a—Si thin layer according to the present invention can be formed more successfully under specific process conditions.

FIGS. 10A and 10B are SEM images of samples of an a—Si thin layer obtained using an Xe sputtering process under different conditions, on which an annealing process is performed.

Specifically, FIG. 10A shows an a—Si layer deposited under a pressure of 8 mT and at an RF power of 200 W, and FIG. 10B shows an a—Si layer deposited under a pressure of 5 mT and at an RF power of 400 W. In both cases, the annealing process is an ELA process performed at an energy density of 550 mJ/cm².

Referring to FIG. 10A, after the ELA process, agglomerations were generated in the a—Si layer. However, referring to FIG. 10B, the a—Si layer was uniformly crystallized into a crystalline Si (poly-Si) layer by the ELA process.

On examining a difference in the quality of a silicon layer affected by process conditions, it can be concluded that a difference in the O₂ content of silicon leads to the difference in the quality of the silicon layer. In particular, when a plastic substrate is used, the difference in the quality of the silicon layer is greatly affected by the process conditions.

FIG. 11 is a graph showing the results of analyses of O₂ content of a bad sample of FIG. 10A and a good sample of FIG. 10B, which are conducted with secondary ion mass spectroscopy (“SIMS”). In FIG. 11, an ordinate refers to intensity, which is an index of O₂ content.

As can be seen from FIG. 11, the good sample has lower O₂ content than the bad sample. Even the good sample has high O₂ content in an early stage of the sputtering process because a native oxide layer is formed on the surface of the good sample. Also, the O₂ content of the good sample sharply jumps in a late stage of the sputtering process (e.g., after 400 sec). This is because silicon is entirely removed by the sputtering process and the underlying SiO₂ layer starts to be sputtered. As shown in FIG. 11, the bad sample has uniform O₂ content irrespective of sputtering time.

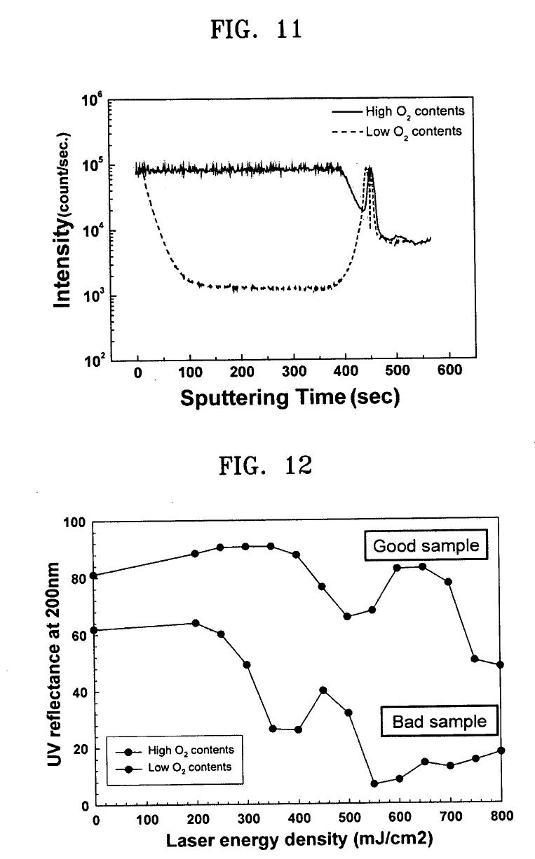

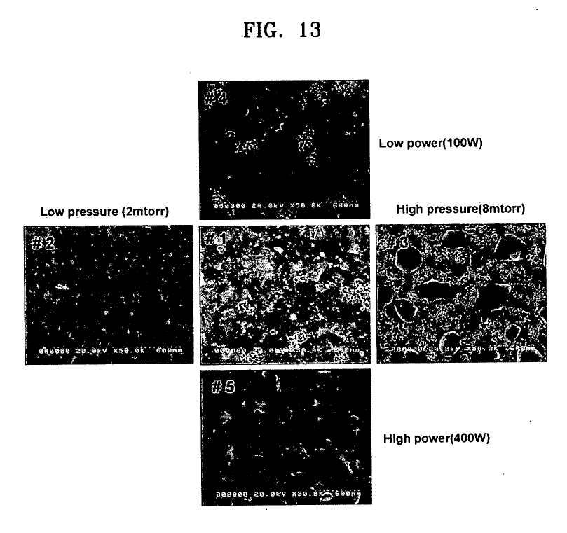

FIG. 12 is a graph of ultraviolet (“UV”) reflectance with respect to laser energy density in the bad and good samples shown in FIGS. 10A and 10B, respectively, each of which was partially annealed at respectively different energy densities in order to look into a relationship between O₂ content and generation of agglomerations in silicon. As can be seen from FIG. 12, when the bad sample with high O₂ content was annealed at various energy levels, the bad sample exhibited generally low UV reflectances as compared with the good sample annealed under the same conditions. The UV reflectance is an index of surface flatness of poly-Si.

In conclusion, a high-quality poly-Si layer can be obtained by lowering the O₂ content of the Si layer. In order to lower the O₂ content of the Si layer, it was experimentally demonstrated that a silicon layer should be formed under a pressure of about 5 mTorr or lower and at an RF power of at least about 200 W.

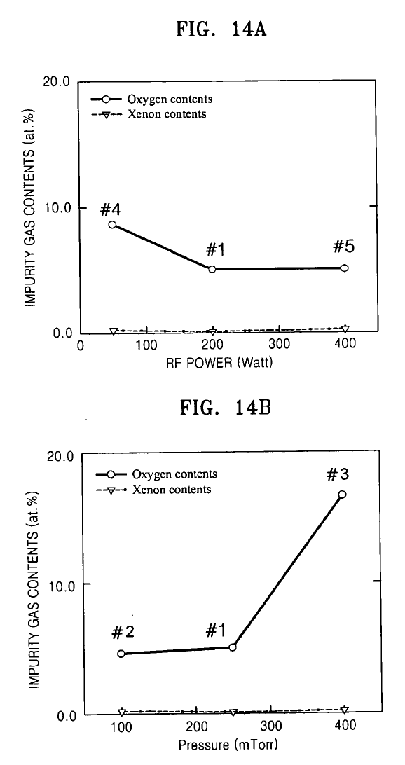

FIG. 13 is an SEM image of samples #1 to #5 of a Si layer that are obtained using an Xe sputtering process under different conditions. The following Table 1 shows working pressures and RF powers corresponding to the samples #1 to #5.

TABLE 1

| | Working Pressure (mTorr) | | |
|---|---|---|---|
| Sputtering Gas: Xe | 2 | 5 | 8 |

| | | | | |
|---|---|---|---|---|
| RF | 50 | | #4 | |
| POWER (W) | 200 | #2 | #1 | #3 |
| | 400 | | #5 | |

In FIG. 13, the sample #1 is a poly-Si layer that is not very good, but usable. The sample 4 is also of poor quality. The samples #2 and #5 are high-quality poly-Si layers. That is, in FIG. 13, the samples #1, #2 and #5 are practicable, but the samples #3 and #4 are inferior in quality so they cannot be used. From the results, in order to obtain a high-quality poly-Si layer from the a—Si layer, the a—Si layer should be formed using an Xe sputtering under a pressure of about 5 mTorr or lower and at an RF power of at least about 200 W.

FIG. 14A is a graph showing the measurements of O₂ content and Xe content of each of the samples #4, #1 and #5 shown in FIG. 13. In FIG. 14A, an abscissa denotes RF power at which the sputtering process was performed, and an ordinate denotes impurity gas content. Here, detection of O₂ was conducted with XPS, and detection of Xe was conducted with RBS. As can be seen from FIG. 14A, the sample #4, which was turned out to be not usable, has a higher O₂ content than the samples #1 and #5, and all the samples #4, #1 and #5 have a very low content of Xe, which was used as a sputtering gas.

FIG. 14B is a graph showing the measurements of O₂ content and Xe content of each of the samples #1, #2 and #3 shown in FIG. 13. In FIG. 14B, an abscissa denotes a working pressure under which the sputtering process was performed, and an ordinate denotes impurity gas content. As can be seen from FIG. 14B, the good samples #1 and #2 have a very low O₂ content, but the sample #3 has a very high O₂ content. Meanwhile, all the samples #1, #2 and #3 have a very low Xe content.

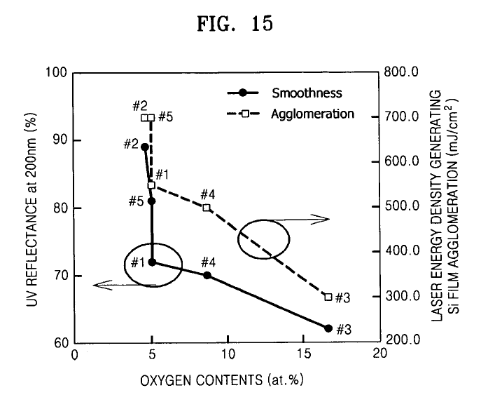

FIG. 15 is a graph of 200 nm-UV reflectance and laser energy density with respect to O₂ content in each of the samples #1 to #5 shown in FIG. 13.

As can be seen from FIG. 15, each of the good samples #1, #2 and #5 have a high UV reflectance. Also, the higher the laser energy density becomes, the better the quality of the Si layer becomes.

As described above, an exemplary embodiment of a sputtering process according to the present invention is performed on an a—Si layer using Xe gas under an appropriate pressure and at an appropriate RF power. In this process, when the a—Si layer is crystallized into a poly-Si layer, no defects are generated in the poly-Si layer due to heat applied during the crystallization of the a—Si layer. Also, since Xe. with a greater mass than Ar is used as a sputtering gas, even if Xe ions collide with a Si target layer, only a small amount of Xe is captured in a substrate. According to the present invention, a high-quality poly-Si layer can be formed not only on a silicon wafer but also on a glass substrate or a plastic substrate.

The present invention can be applied to a method of forming a poly-Si by crystallizing an a—Si layer. More specifically, the present invention can be used for manufacturing products formed of poly-Si, for example, thin film transistors (“TFTs”) for a memory device and a flat panel display (“FPD”).

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a silicon (Si) thin layer comprising:
making xenon (Xe) ions generated by radio frequency(RF) power collide with a silicon target material layer to generate silicon particles from the silicon target material layer; and
depositing the silicon particles on a predetermined substrate,
wherein the method is performed under a pressure of about 5 mTorr or lower and at an RF power of about 200 W or more.

2. The method of claim 1, further comprising annealing the deposited silicon particles at a predetermined temperature.

3. The method of claim 1, wherein the deposited silicon particles are annealed using an eximer laser.

4. The method of claim 2, wherein the deposited silicon particles are annealed using an eximer laser.

5. The method of claim 3, wherein the substrate is one of a glass substrate and a plastic substrate.

6. The method of claim 4, wherein the substrate is one of a glass substrate and a plastic substrate.

7. The method of claim 1, wherein the substrate is one of a glass substrate and a plastic substrate.

8. The method of claim 2, wherein the substrate is one of a glass substrate and a plastic substrate.

9. The method of claim 2, wherein the predetermined temperature is about 500° C.
